(19) United States
(12) Patent Application Publication
(10) Pub. No.: US 2011/0241115 A1
(43) Pub. Date: Oct. 6, 2011

(54) Schottky Junction Source/Drain FET Fabrication Using Sulfur or Flourine Co-Implantation

(75) Inventors: Christian Lavoie, Pleasantville, NY (US); Siegfried L. Maurer, Stormville, NY (US); Qiqing Ouyang, Yorktown Heights, NY (US); Paul Solomon, Yorktown Heights, NY (US); Zhen Zhang, Ossining, NY (US)

(73) Assignee: INTERNATIONAL BUSINESS MACHINES CORPORATION, Armonk, NY (US)

(21) Appl. No.: 12/754,079

(22) Filed: Apr. 5, 2010

(51) Int. Cl. H01L 27/12; H01L 21/762; H01L 21/28

(52) U.S. Cl. 257/347; 438/151; 438/682; 257/E21.158; 257/E21.561; 257/E27.112

(57) ABSTRACT

A Schottky field effect transistor (FET) includes a gate stack located on a silicon on insulator (SOI) layer, the gate stack comprising a gate silicide region; and source/drain silicide regions located in the SOI layer, the source/drain silicide regions comprising and at least one of sulfur and fluorine, wherein an interface comprising arsenic is located between each of the source/drain silicide regions and the SOI layer. A method of forming a contact, the contact comprising a silicide region adjacent to a silicon region, includes co-implanting the silicide region with arsenic and at least one of sulfur and fluorine; and drive-in annealing the co-implanted silicide region to diffuse the arsenic to an interface between the silicide region and the silicon region.

### FIELD

This disclosure relates generally to the field of fabrication of Schottky junction source/drain semiconductor devices.

### DESCRIPTION OF RELATED ART

A Schottky junction source/drain metal-oxide-semiconductor (MOS) field effect transistor (FET) is a viable option for thin-body devices and sub-30 nm gate CMOS technology Schottky FETs may have relatively low parasitic resistance and gate-to-drain parasitic capacitance, due to the lack of raised source/drain regions, as well as abrupt source/drain junctions. However, a Schottky barrier height (SBH) at the source/drain junction approaching zero is needed to achieve a competitive current drive in Schottky FET devices.

### SUMMARY

In one aspect, a method for forming a Schottky junction field effect transistor (FET) includes forming a gate stack comprising gate polysilicon on a silicon-on-insulator (SOI) layer; simultaneously forming a gate silicide region from the gate polysilicon and forming source/drain silicide regions in the SOI layer; co-implanting the source/drain silicide regions with arsenic and at least one of sulfur and fluorine; and drive-in annealing the co-implanted source/drain silicide regions to diffuse the arsenic to an interface between the each of source/drain silicide regions and the SOI layer.

In one aspect, a Schottky field effect transistor (FET) includes a gate stack located on a silicon on insulator (SOI) layer, the gate stack comprising a gate silicide region; and source/drain silicide regions located in the SOI layer, the source/drain silicide regions comprising and at least one of sulfur and fluorine, wherein an interface comprising arsenic is located between each of the source/drain silicide regions and the SOI layer.

In one aspect, a method of forming a contact, the contact comprising a silicide region adjacent to a silicon region, includes co-implanting the silicide region with arsenic and at least one of sulfur and fluorine; and drive-in annealing the co-implanted silicide region to diffuse the arsenic to an interface between the silicide region and the silicon region.

Additional features are realized through the techniques of the present exemplary embodiment. Other embodiments are described in detail herein and are considered a part of what is claimed. For a better understanding of the features of the exemplary embodiment, refer to the description and to the drawings.

### BRIEF DESCRIPTION OF THE SEVERAL VIEWS OF THE DRAWINGS

Referring now to the drawings wherein like elements are numbered alike in the several FIGURES:

FIG. 1 illustrates an embodiment of a method for forming a FET using sulfur or fluorine co-implantation.

FIG. 2 illustrates an embodiment of shallow trench isolation regions formed in a silicon-on-insulator layer.

FIG. 3 illustrates an embodiment of the device of FIG. 2 after formation of a gate stack and spacers.

FIG. 4 illustrates an embodiment of the device FIG. 3 after formation of silicide gate and source/drain regions.

FIG. 5 illustrates an embodiment of the device of FIG. 4 during implantation with arsenic and sulfur or fluorine.

FIG. 6 illustrates an embodiment of a FET formed using sulfur or fluorine co-implantation.

### DETAILED DESCRIPTION

Embodiments of systems and methods for fabricating a Schottky S/D device using sulfur or fluorine co-implantation are provided, with exemplary embodiments being discussed below in detail. A method of engineering the SBH of a Schottky S/D device is to implant dopants into the source/drain silicides followed to rapid thermal anneal to diffuse the implanted dopants to the silicide/Si channel interface. Normally boron is used for p-FETs and arsenic (As) or phosphorus (P) are used for n-FETs. A drive-in anneal temperature of at least 600° C. is required to enable a maximized SBH tuning by As/P. In particular, for the case of a silicide region implanted with As, and then drive-in annealed to diffuse the As to an interface between the silicide and a silicon (Si), arsenic segregation requires that the anneal be performed at a temperature of at least 600° C. to fully diffuse the As to the interface. This relatively high anneal temperature may lead to silicide agglomeration, especially when the silicide thickness is less than 10 nm. The required anneal temperature may be lowered by co-implantation of sulfur (S) or fluorine (F) with the As. The presence of the S or F causes the As to fully diffuse to the interface at an anneal temperature of less than about 600° C., and between about 500° C. and 550° C. in some embodiments, increasing stability of the device during the anneal while lowering the SBH of the silicide junction. While co-implantation of S or F with As is discussed below with regards to FET fabrication, S or F co-implantation with As may be used to lower the SBH of any appropriate junction having an SBH, such as a silicide contact.

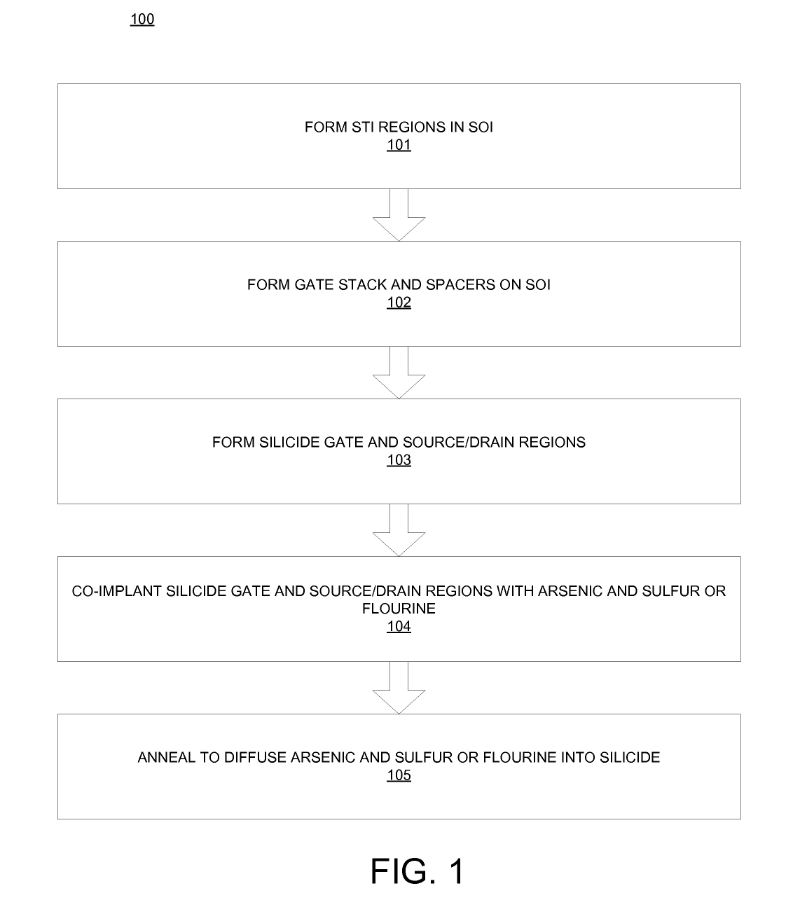

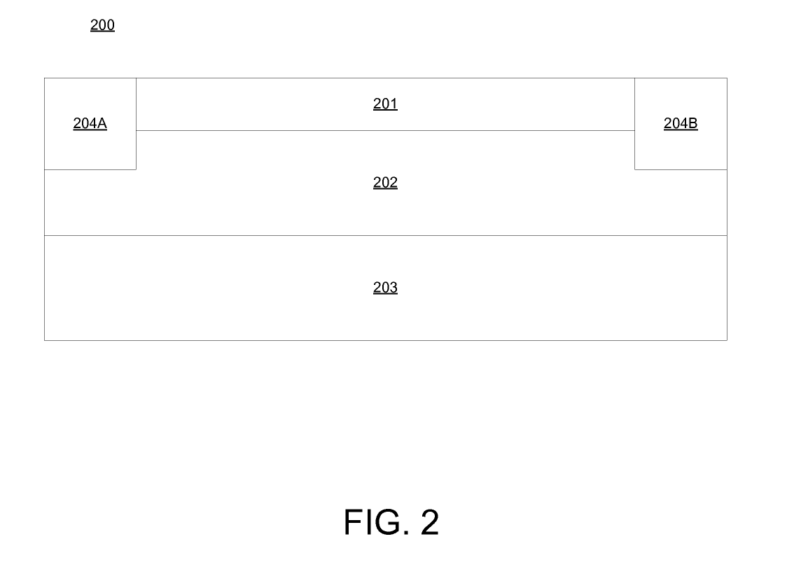

FIG. 1 illustrates a method for fabricating a FET using sulfur or fluorine co-implantation. FIG. 1 is discussed with reference to FIGS. 2-5. In block 101, shallow trench isolation regions 204A-B are formed in silicon-on-insulator (SOI) layer 201 and buried oxide 202, as is shown in FIG. 2. SOI layer 201 is located on a buried oxide layer 202, which is in turn located on substrate 203. STI regions 204A-B may be formed by thinning of SOI layer 201 using thermal oxidation. SOI layer 201 comprises an undoped channel region for the FET, and may have a thickness of less than about 10 nanometers (nm).

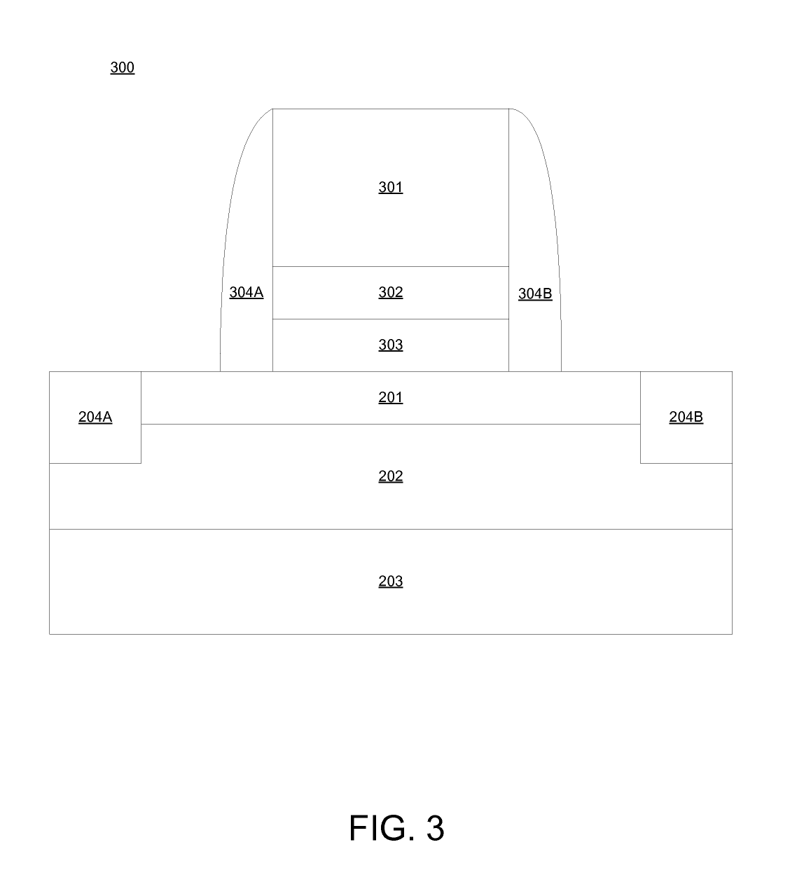

In block 102, a gate stack comprising polysilicon layer 301, metal layer 302, and high-k dielectric layer 303 is formed on SOI layer 201, and spacers 304A-B are formed adjacent to the gate stack on SOI layer 201, as is shown in FIG. 3. The gate stack may have a mid-gap work-function in some embodiments. High-k dielectric layer 303 may be hafnium-based in some embodiments. The gate stack may be formed by patterning polysilicon layer 301, metal layer 302, and high-k layer 303 using e-beam lithography in some embodiments. Reactive ion etching may then be used to form a gate stack having a gate length of about 20 nm. Spacers 304A-B may then be formed adjacent to the gate stack. Spacers 304A-B may comprise nitride, and may have a width of less than about 10 nm in some embodiments. After spacer formation, device 300 may be annealed in some embodiments; the anneal may comprise a forming gas anneal of about 475° C. for 30 minutes.

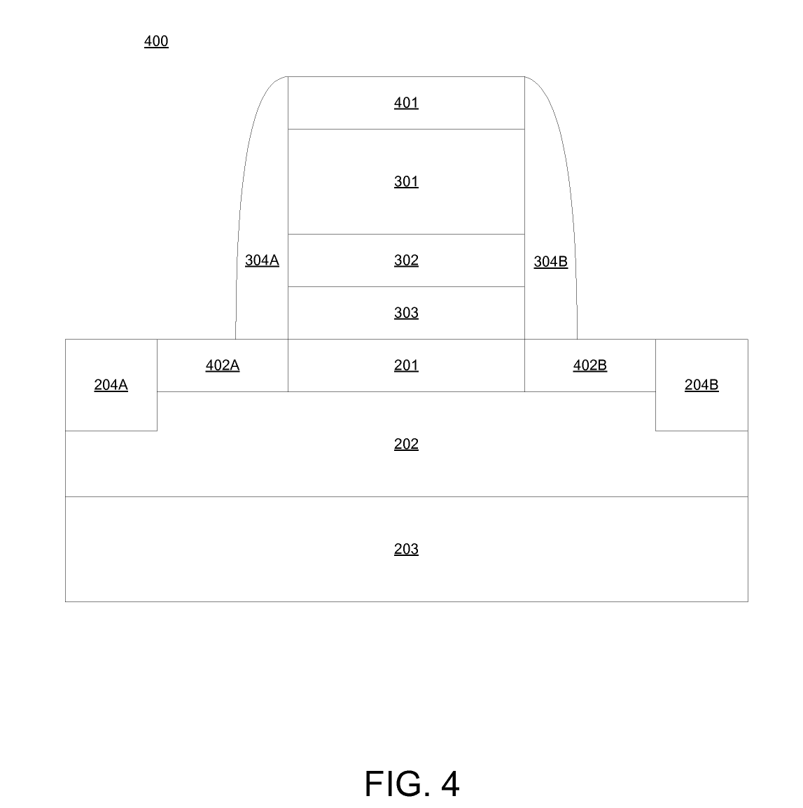

In block 103, the SOI layer 201 and polysilicon layer 301 are silicided, forming gate silicide 401 and source/drain silicide 402A-B, as shown in FIG. 4. The silicide may be formed by depositing a layer of a metal, for example, nickel (Ni) or nickel platinum (NiPt), on polysilicon layer 301 and on the exposed portion of SOI layer 201 (of FIG. 3), annealing the device 400 after the metal deposition to cause the metal to react with polysilicon layer 301 and SOI layer 201, and removing any unreacted metal, resulting in gate silicide 401 and source/drain silicide 402A-B, as shown in FIG. 4. Source/drain silicide regions 402A-B reach the edge of the gate stack. The material comprising spacers 304A-B may be selected such that spacer 304A-B do not react with the deposited metal.

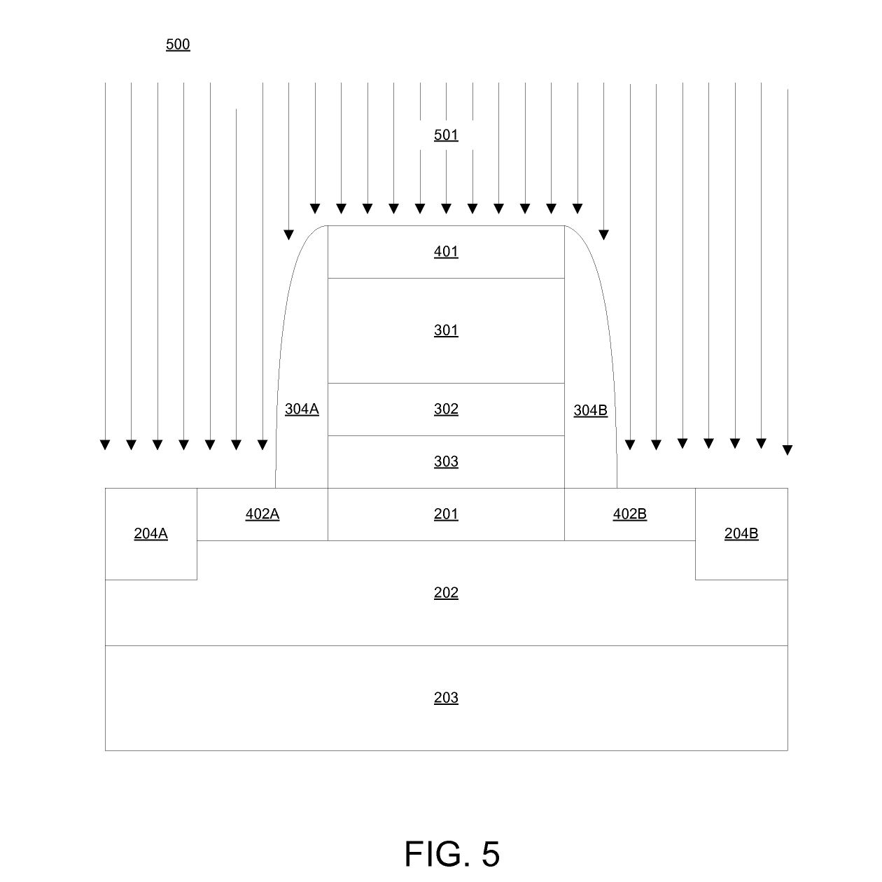

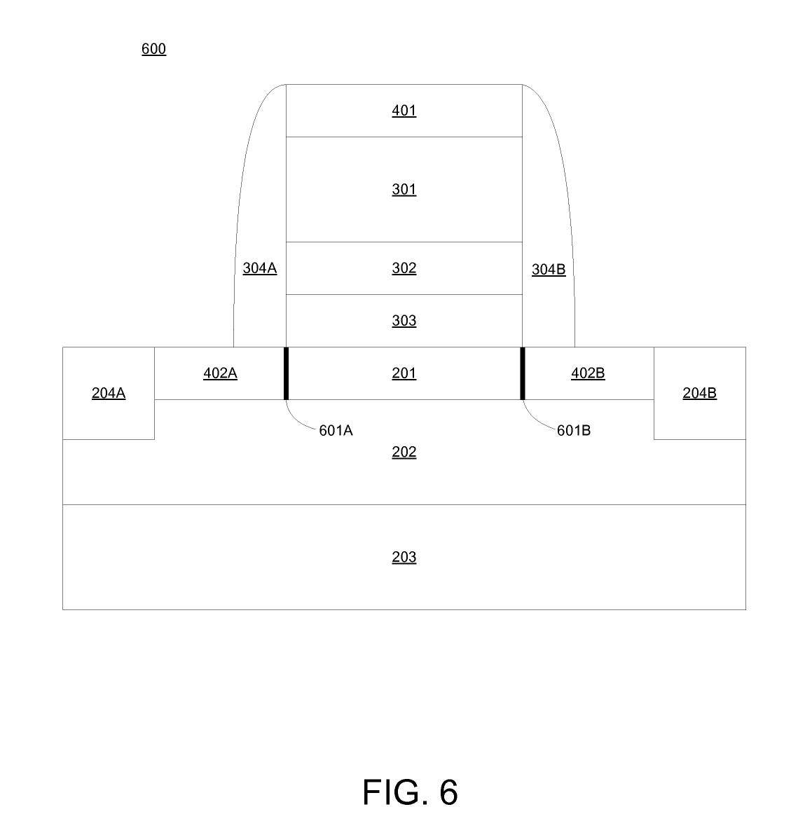

In block 104, gate silicide 401 and source/drain silicide 402A-B are co-implanted with dopants as shown in FIG. 5. Co-implantation 501 may comprise low-energy implantation with As, followed by implantation with at least one of S or F. Then, in block 105, the co-implanted device 500 is drive-in annealed, causing the As to form interfaces 601A-B between SOI 201 and source/drain silicide 402A-B, as shown in FET 600 of FIG. 6. The S or F co-implantation performed in block 104 causes the co-implanted As to diffuse into source/drain silicide 402A-B to interfaces 601A-B at a lower temperature than is necessary to diffuse As alone. The diffused As causes FET 600 to have a relatively low SBH at interfaces 601A-B. The co-implanted S or F may remain in source/drain silicide 402A-B after the drive-in anneal. FET 600 comprises an nFET device, and may comprise a Schottky FET device. FET 600 may have a gate length of less than 30 nm in some embodiments. The drive-in anneal maybe performed at a temperature below about 600° C., and between about 500° C. and 550° C., and may have a duration of more than 5 seconds, and between about 30 and 60 seconds in some embodiments.

The technical effects and benefits of exemplary embodiments include formation of a relatively thin, low-SBH silicided junction.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A method for forming a Schottky field effect transistor (FET), the method comprising:
forming a gate stack comprising gate polysilicon on a silicon-on-insulator (SOI) layer;
simultaneously forming a gate silicide region from the gate polysilicon and forming source/drain silicide regions in the SOI layer;
co-implanting the source/drain silicide regions with arsenic and fluorine; and
drive-in annealing the co-implanted source/drain silicide regions to diffuse the arsenic to an interface between the each of source/drain silicide regions and the SOI layer.

2. The method of claim 1, further comprising forming at least one shallow trench isolation (STI) region in the SOI layer.

3. The method of claim 1, wherein the gate stack comprises a layer of a high-k dielectric comprising hafnium on the SOI layer, a gate metal layer over the high-k material, and the gate polysilicon located over the gate metal layer.

4. The method of claim 1, further comprising forming at least one spacer comprising a nitride material adjacent to the gate stack on the SOI layer.

5. The method of claim 1, wherein the drive-in annealing is performed at a temperature below about 600° C.

6. The method of claim 1, wherein the drive-in annealing has a duration of more than about 5 seconds.

7. The method of claim 1, wherein simultaneously forming a gate silicide region from the gate polysilicon and forming source/drain silicide regions in the SOI layer comprises:
forming a metal layer over the gate polysilicon and the SOI layer;
annealing the metal layer, the gate polysilicon, and the SOI layer such that the metal layer reacts with the gate polysilicon to form the gate silicide and reacts with a portion of the SOI layer to form the source/drain silicide regions; and
in the event a portion of the metal layer does not react with the gate polysilicon or the SOI layer, removing the unreacted portion of the metal layer.

8. The method of claim 7, wherein the metal layer comprises nickel or nickel platinum.

9. The method of claim 1, wherein the SOI layer has a thickness of less than about 10 nanometers.

10. A Schottky field effect transistor (FET), comprising:
a gate stack located on a silicon on insulator (SOI) layer, the gate stack comprising a gate silicide region; and
source/drain silicide regions located in the SOI layer, the source/drain silicide regions comprising and at least one of sulfur and fluorine, wherein an interface comprising arsenic is located between each of the source/drain silicide regions and the SOI layer.

11. The FET of claim 10, wherein the gate stack comprises a layer of a high-k dielectric comprising hafnium on the SOI layer, a gate metal layer over the high-k material, and the gate silicide region located over the gate metal layer.

12. The FET of claim 10, further comprising at least one spacer comprising a nitride material located adjacent to the gate stack on the SOI layer.

13. The FET of claim 10, wherein the gate silicide and the source/drain silicide regions further comprise one of nickel or nickel platinum.

14. The FET of claim 10, wherein the SOI layer has a thickness of less than about 10 nanometers.

15. The FET of claim 10, wherein the FET has a gate length of less than about 30 nanometers.

16. A method of forming a contact, the contact comprising a silicide region adjacent to a silicon region, the method comprising:
co-implanting the silicide region with arsenic and at least one of sulfur and fluorine; and
drive-in annealing the co-implanted silicide region to diffuse the arsenic to an interface between the silicide region and the silicon region.

17. The method of claim 16, wherein the silicide region comprises one of nickel or nickel platinum.

18. The method of claim 16, wherein the drive-in annealing is performed at a temperature below about 600° C.

19. The method of claim 16, wherein the drive-in annealing has a duration of more than about 5 seconds.
